(19) United States
(12) Patent Application Publication
(10) Pub. No.: US 2004/0224508 A1
(43) Pub. Date: Nov. 11, 2004

(54) Apparatus and method for cleaning a substrate using a homogenized and non-polarized radiation beam

(75) Inventors: Michael Engel, Misgav (IL); David Yogev, Nesher (IL); Lev Frisman, Zichron- Yaakov (IL)

Correspondence Address: PATENT COUNSEL, APPLIED MATERIALS, INC., Legal Affairs Department, P.O. BOX 450A, Santa Clara, CA, 95052, US

(73) Assignee: Applied Materials Israel Ltd

(21) Appl. No.: 10/431,074

(22) Filed: May 6, 2003

(51) Int. Cl. H01L 21/302; H01L 21/461

(52) U.S. Cl. 438/689

(57) ABSTRACT

Apparatus and method for cleaning of a substrate by a homogenized and de-polarized radiation beam, the apparatus includes: (i) a radiation source which is adapted to emit a non-homogenized and polarized radiation beam toward a de-polarizer and homogenizer; (ii) a de-polarizer and homogenizer, for converting the non-homogenized and polarized radiation beam to a homogenized and de-polarized radiation beam; and (iii) optics, for directing the homogenized and de-polarized radiation beam towards the substrate.

### FIELD OF THE INVENTION

The present invention relates generally to processing of semiconductor devices, and specifically to methods and apparatus for removal of particles and contaminants from solid-state surfaces, such as semiconductor wafers and lithography masks.

### BACKGROUND OF THE INVENTION

Removal of particles and contaminants from solid-state surfaces is a matter of great concern in integrated circuit manufacture. This concern includes, but is not limited to, semiconductor wafers, printed circuit boards, component packaging, and the like. As the trend to miniaturize electronic devices and components continues, and critical dimensions of circuit features become ever smaller, the presence of even a minute foreign particle on a substrate wafer during processing can cause a fatal defect in the circuit. Similar concerns affect other elements used in the manufacturing process, such as masks and reticles.

Various methods are known in the art for stripping and cleaning foreign matter from the surfaces of semiconductor wafers and masks, while avoiding damage to the surface itself. For example, U.S. Pat. No. 4,980,536, whose disclosure is incorporated herein by reference, describes a method and apparatus for removal of particles from solid-state surfaces by laser bombardment. U.S. Pat. Nos. 5,099,557 and 5,024,968, whose disclosures are also incorporated herein by reference, describe methods and apparatus for removing surface contaminants from a substrate by high-energy irradiation. The substrate is irradiated by a laser with sufficient energy to release the particles, while an inert gas flows across the wafer surface to carry away the released particles.

### SUMMARY OF THE INVENTION

The present invention provides methods and apparatus for efficient removal of particles from solid-state surfaces and from other elements used in semiconductor device production. In the context of the present patent application and in the claims, the word “particle” is used broadly to refer to any contaminant or other foreign substance that shall be removed from a surface of the substrate.

In an embodiment of the present invention, a radiation beam is both homogenized and de-polarized prior interacting with a substrate for the removal of particles. Conveniently, the radiation beam is homogenized and at least partially de-polarized by a multi-mode optic fiber that is positioned in the path of the beam.

According to an aspect of the invention the optical axis of the homogenized and de-polarized radiation beam is normal to the substrate.

In some embodiments, the homogenized and de-polarized radiation beam is used in conjunction with a particle location system, which determines the locations of particles on the surface. In such embodiments, the homogenized and de-polarized radiation beam need not be applied over the entire surface, but rather may be directed specifically to the locations at which particles (or suspected particles) are detected.

In further embodiments of the present invention, the homogenized and de-polarized radiation beam may be directed towards a film of fluid that is deposited to coat the surface and any particles in the area. Then, the homogenized and de-polarized radiation beam is applied to the same area of the surface. The homogenized and de-polarized radiation beam is absorbed by the fluid, causing the fluid to evaporate explosively.

In yet further embodiments of the present invention, the homogenized and de-polarized radiation beam may be directed towards an iced film that is deposited to coat the surface and any particles in the area. Then, the homogenized and de-polarized radiation beam is applied to the same area of the surface. The homogenized and de-polarized radiation beam is absorbed by the iced film, causing the iced film to evaporate explosively.

### BRIEF DESCRIPTION OF THE DRAWINGS

The present invention will be more fully understood from the following detailed description of certain embodiments thereof, taken together with the drawings in which:

FIG. 1 is a schematic view of a particle removal system;

FIG. 2-3 are schematic views of particle removal apparatuses, in accordance with embodiments of the present invention; and

FIG. 4 is a flow chart illustrating a method in accordance with various embodiments of the present invention.

### DETAILED DESCRIPTION OF EMBODIMENTS

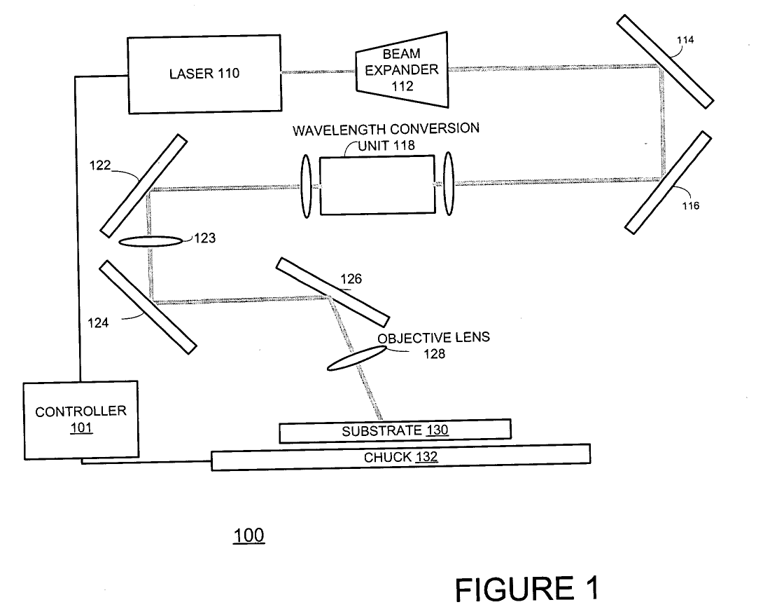

Reference is now made to FIG. 1, which is a schematic view of a particle removal system 100. FIG. 1, as well as other figures are not at scale, and for simplicity of explanation do not include various components.

System 100 includes a horizontally oriented laser source 110 that is adapted to generate a de-homogenized and linearly polarized light beam 111. Source 110 is followed by beam expander 112, two mirrors 114 and 116 for directing the expanded de-homogenized and linearly polarized light beam towards wavelength conversion unit 118. Wavelength conversion unit converts the wavelength of the de-homogenized and linearly polarized light beam from 1.06 micron to 2.94 micron while substantially maintaining the beams polarization and non-homogenization characteristics. Wavelength conversion unit 118 is followed by mirror 122, lens 123, mirrors 124 and 126 that direct the de-homogenized and linearly polarized light beam via a focusing lens 128 towards substrate 130 in an acute angle.

Substrate 130 is supported by chuck 132. Chuck 132 can be a non-contact chuck that generates an air bearing on which substrate 130 floats.

Chuck 132 may be moved in relation to the homogenized and de-polarized radiation beam such to enable scanning of the substrate by said homogenized and de-polarized radiation beam. The displacement of the chuck 132 as well as the operation of laser source 110 are controller by controller 101. It is noted that controller 101 may include multiple hardware and software components that may co-operate with each other.

The use of air bearings generally, and air bearing chucks in particular, in semiconductor processing equipment is known in the art. Such chucks are produced, for example, by CoreFlow Ltd. (Yokneam, Israel). As another example, U.S. Pat. No. 5,898,179, whose disclosure is incorporated herein by reference, describes a mechanical scanning apparatus for moving a semiconductor wafer inside a vacuum chamber, based on air bearing seals, which supports both linear and rotary motion.

The inventors found out that system 100 is characterized by a relatively limited process window. A process window is defined by a process threshold and by a damage threshold. Laser beams that are characterized by flux (energy per unit area) that are below the process threshold do not enable efficient particle removal. On the other hand laser beams that are characterized by flux above the damage threshold may cause damage to the substrate.

A further disadvantage of system 100 relayed on its dependency upon laser source calibration for achieving desired beam homogeneity. It is known in the art that a laser source can be calibrated to achieve a substantially predetermined beam profile. The calibration has to take into account various parameters such as but not limited to the laser type, its mode of operation, the distance between the laser and its output aperture and the like. In order to achieve high beam homogeneity each laser had to undergo a time consuming calibration, whereas said calibration was also responsive to the characteristics of the wavelength converter, the relative location of the components of system 100 and the like.

The invention is based upon three assumptions, that relate to the increment of the damage threshold and accordingly the process window: (1) both may be incremented by directing the beam at substantially a normal angle to the substrate; (2) both may be incremented by de-polarizing the beam; (3) both may be incremented by homogenizing the beam.

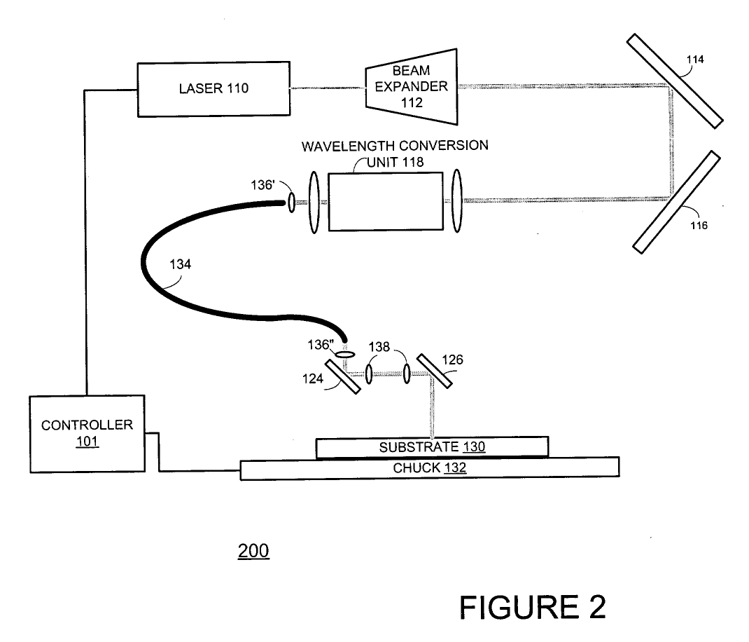

FIG. 2 illustrates system 200 in accordance to an aspect of the invention. System 200 differs from system 100 by the absence of mirror 124 and lens 123, and by the inclusion of multi-mode fiber 134 and fiber optics 136. System 200 also includes optics for directing the homogenized and de-polarized radiation beam towards substrate 130, said optics may differ from the optics of system 100, as illustrated in FIG. 2 in which relay lenses are added.

The multi-mode fiber 134 converts the polarized and de-homogenized light beam to a homogenized and de-polarized radiation beam due to the multi-modal propagation of the beam components through the multi-mode fiber that smoothes/smears the various components of the beam. The multi-modal fiber has to be long enough to achieve smoothing of the light beam. The inventor used a 1 Meter long long, 420-micrometer diameter Sapphire made multi-modal fiber, but other multi-modal fibers of various diameters, materials and lengths may be utilized. The inventor further noticed that if the beam exits the multi-modal fiber with residual polarity, this residual polarity can be substantially cancelled by additional de-polarization means, such as but not limited to a retarder plate.

The fiber optics 136 includes an input lens 136′ and an output lens 136″. Input lens 136′ de-magnifies the non-homogenized and polarized beam and directs it into multi-mode fiber 134. Output lens 136″ magnifies the homogenized and de-polarized radiation beam and directs it towards mirror 124, relay optics 138 and mirror 126 such that the homogenized and de-polarized radiation beam is directed at substantially a normal angle towards the substrate. Mirror 124, relay optics 138 and mirror 126 are generally termed “optics” although system 200 may include additional optical elements.

The inventors have found that the multi-modal fiber 134 compensates for beam shaping variations and thus laser source calibration may be eliminated.

It is noted that the non-homogeneity of the beam resulted in a range of maximal possible flux values. When operating system 100 the highest maximal flux value had to be taken into account, thus reducing the maximal flux of the laser beam. Once the multi-mode fiber was used, the range of maximal flux values is largely reduces, as well as the uncertainty associated with the maximal flux value, thus allowing to generate higher flux laser beams.

Typically, substrate 130 is a semiconductor wafer. Alternatively the substrate in this and other embodiments described herein may be a mask, reticle, or substantially any other flat element requiring a very high standard of cleanliness.

According to an aspect of the invention the homogenized and de-polarized radiation beam is applied and is immediately followed by application of suction by suction head 140 or even by applying a flow of gas that carries away the removed particles. The suction serves to remove a particle once it is dislodged, preventing its re-deposition onto substrate 130.

The system may scan over and clean the entire surface of substrate 130, or it may alternatively be directed to clean only particular locations at which particles are known or suspected to exist.

The location of a particle may be determined using an inspection station (not shown in the figures). The inspection station determines the coordinates of particle on substrate 130. The coordinates are passed to controller 101, which stores the coordinates and transforms them to a coordinate frame of system 200. The coordinates are used to direct the radiation beam to remove the particles from the surface. Alternatively, the inspection station may be constructed together with system 200 as a single, integral unit, which both determines the particle coordinates and removes the particles accordingly, without the need to transfer substrate 130 from one entity to the next.

The inspection station may comprise any suitable automated inspection system known in the art, such as those described in U.S. Pat. Nos. 5,264,912, 4,628,531, and 5,023,424, whose disclosures are incorporated herein by reference. For example, the Applied Materials “Compass” or KLA-Tencor “Surfscan” systems may be used for this purpose. Typically, a laser irradiates substrate 130, and a detector senses irregularities in the radiation reflected from the surface. Alternatively, other inspection methods, such as optical microscopy or scanning electron microscopy (SEM), may be employed. The irregularities are analyzed to determine the coordinates of particle.

U.S. patent application Ser. No. 09/869,058, and PCT Patent Application PCT/IL99/00701 which are assigned to the assignee of the present patent application, and whose disclosures are incorporated herein by reference, likewise describe the use of particle localization systems to determine coordinates of particles to be removed from the substrate surface. The coordinates may be converted to polar coordinates, for use in driving the rotation of the chuck holding the substrate and scanning of the cleaning assembly.

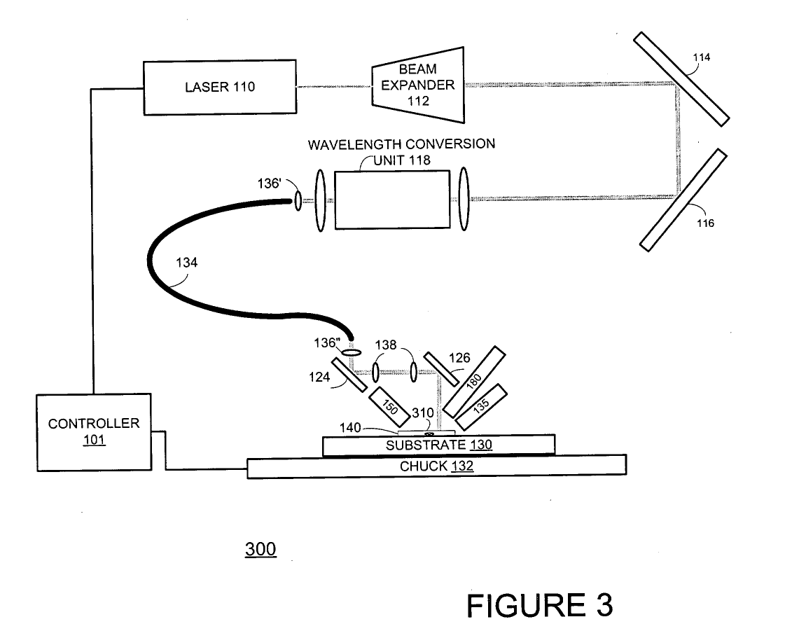

Referring to FIG. 3 illustrating system 300, in accordance to another aspect of the invention. System 300 differs from system 200 by having in addition cold nozzle 150 and a vapor nozzle 135 for allowing iced film substrate cleaning.

Substrate 130 is maintained in position upon a chuck 132 or motion stage. A particle 310 shown in the figure is representative of one or more particles located on a surface of the substrate 130. Typically, substrate 130 is a semiconductor wafer, and its surface may be un-patterned, or it may be patterned, with one or more material layers formed on the surface. Alternatively the substrate in this and other embodiments described herein may be a mask, reticle, or substantially any other flat element requiring a very high standard of cleanliness.

Cleaning of particle 310 from the surface is accomplished by directing a cold stream mixture, such as a mixture of high-velocity frozen and gaseous CO₂, towards the area of particle 310 from a cold nozzle 150. The above-mentioned “snow” nozzles provided by Applied Surface Technologies, for example, may be used for this purpose. Alternatively, other means known in the art, such as a stream of liquid nitrogen or other chilled gas and/or liquid, may be used to cool the area of the particle, or to cool the entire substrate. The cold stream mixture and other parameters are controlled to locally and rapidly cool the area of particle 310 and the surrounding area of the surface. Preferably, vapor nozzle 135 is maintained from 1-2 mm above the surface and the cold stream mixture is applied for up to 0.1 seconds.

Simultaneously with or immediately following cooling of the surface by the cold stream, a controlled stream of gas, saturated with a condensable vapor, is directed towards the area of particle 310, from a vapor nozzle 135. The stream of gas with saturated vapor, typically water, contacts the cooled area adjacent to particle 310, and forms a frozen film 140, typically ice, around particle 310. The timing, direction, composition, temperature and intensity of the cold stream mixture and of the gas/vapor stream are controlled to yield pre-selected lateral dimensions and thickness of frozen film 140 upon the surface. Preferably, frozen film 140 has a diameter of up to 1 mm and a thickness of up to 10 μm, although films of larger or smaller dimensions may also be used for the purposes of the present invention. Variations in the height of vapor nozzle 135 above the surface directly affect the dimensions of frozen film 140 and the time required for cold stream mixture application. For example, in one set of measurements in which the vapor nozzle was maintained 5 to 7 mm above the surface, and a frozen and gaseous CO₂ cold stream mixture was applied for 0.5 seconds, frozen film 140 exhibited a diameter ranging from approximately 5 to 7 mm and a thickness of up to approximately 50 μm. Holding the vapor nozzle closer to the surface generally yields a smaller, thinner film.

The homogenized and de-polarized radiation beam is directed towards the area of particle 110. The energy is absorbed by frozen film 140, causing the film to explosively evaporate and thereby dislodge particle 110. A suction nozzle 160 may be provided adjacent to the surface 120 in order to remove particle 110 and the other products of the explosive evaporation. The wavelength of the homogenized and de-polarized radiation beam may be chosen for optimal interaction with the medium in film 140. For example, if vapor nozzle 135 emits water vapor, so that frozen film 140 comprises ice, a laser operating at or near the water absorption peak of 2.94 μm may be used. At this wavelength, nearly all the laser radiation is absorbed by a relatively thin film of ice, yielding a strong explosive effect without damage to surface 120. Alternatively, other wavelengths and other types of frozen films may be used, as will be apparent to those skilled in the art. Further details of exemplary surface cleaning processes based on explosive evaporation, which may be applied in system 300, are described in PCT Patent Application PCT/IL99/00701, in U.S. Pat. No. 4,987,286 and in U.S. patent application Ser. No. 09/721,167, which are assigned to the assignee of the present patent application, and whose disclosures are incorporated herein by reference.

System 300 may alternatively be used to clean particles from the surface using ambient humidity in the atmosphere above the surface to provide vapor, in place of vapor nozzle 135. In other respects, formation of frozen film 140 and subsequent firing of the homogenized and de-polarized radiation beam is substantially the same as described hereinabove.

The use of frozen film 140 described hereinabove avoids certain problems found in methods of explosive evaporation using liquid films. Frequently, when a condensable vapor is use to create a liquid film on the surface, individual droplets may form, instead of the formation of a uniform liquid film. As a result, portions of the surface may be exposed to direct irradiation. In order to reduce the risk of damage to the surface, irradiation levels are reduced, with a concomitant reduction in effectiveness of particulate removal. An additional problem, related to droplet formation, is that of a laser energy field intensity enhancement. This problem is described by H. J. Munzer et al., in “Optical Near Field Effects in Surface Nanostructuring and Laser Cleaning”, presented at the Laser Precision Microfabrication 2001 Conference (LPM2001, May 18, 2001), whose disclosure is incorporated herein by reference. This paper describes energy field intensity enhancement due to small particles on a surface, which substantially increase laser fluence beneath the particles, causing damage to the surface. The inventors have found that a similar problem of field intensity enhancement can occur due to liquid droplets on the surface to be cleaned.

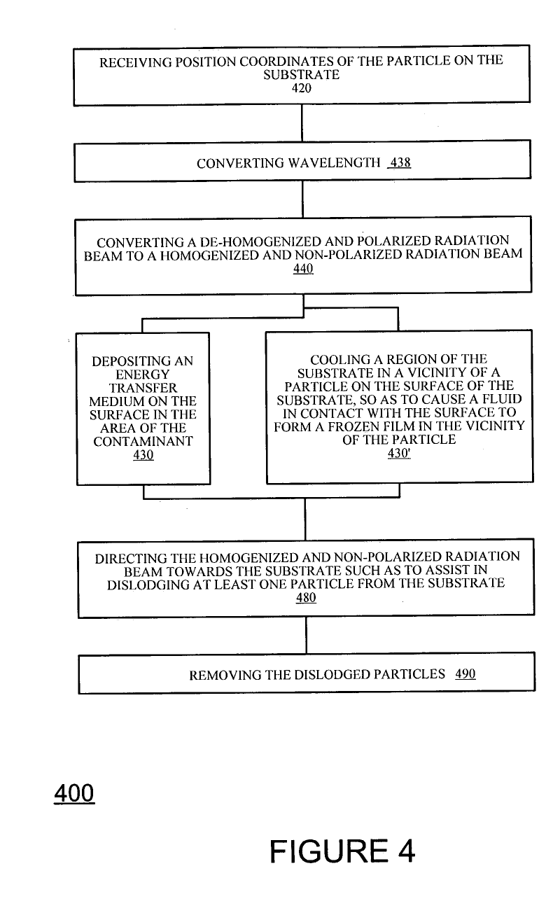

Referring to FIG. 4 illustrating a method for cleaning a substrate. Method 400 includes step 440 of converting a de-homogenized and polarized radiation beam to a homogenized and non-polarized radiation beam and step 480 of directing the homogenized and non-polarized radiation beam towards the substrate such as to assist in dislodging at least one particle from the substrate. Step 440 may involve passing the non-homogenized and polarized radiation beam through a multi-mode fiber, such as multi mode fiber 134 of FIGS. 2 and 3. Step 440 may further involve directing the radiation beam through a retarding plate located in succession of an output (The retarder plate is in the input side of the fiber) of the multi-mode fiber in the path of the radiation beam. Step 480 may involve directing the homogenized and de-polarized radiation beam towards the substrate at a substantially normal angle.

Method 400 may include additional steps such as a step (now shown) of scanning the surface by the homogenized and de-polarized radiation beam so as to clean at least an area of the surface in which a particle is located.

Step 440 may be preceded by step 420 of receiving position coordinates of the particle on the substrate. In such a case step 480 may include causing the homogenized and de-polarized radiation beam to clean the surface locally at a location indicated by the coordinates.

Step 440 may be preceded by step 438 of converting a wavelength of the polarized and de-homogenized radiation beam.

According to another aspect of the invention step 440 is preceded by step 430 of depositing an energy transfer medium on the surface in the area of the contaminant. In such a case step 480 may involve directing the homogenized and de-polarized radiation beam onto the area, wherein the energy is absorbed by the medium, thereby causing local evaporation of the medium, so as to dislodge the particle. The medium may be a fluid and it may be deposited by a fluid nozzle (not shown).

Method 400 may include a preliminary step 430′ of cooling a region of the substrate in a vicinity of a particle on the surface of the substrate, so as to cause a fluid in contact with the surface to form a frozen film in the vicinity of the particle. In such a case step 480 may involve directing the homogenized and de-polarized radiation beam toward the film so as to cause rapid evaporation due to absorption of at least a portion of the beam in the film, thereby assisting in dislodging the particle from the surface.

Step 480 may be followed by step 490 of removing the dislodged particles, by various means such as by applying suction or by introducing a flow of gas.

It will be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. Apparatus for cleaning a surface of a substrate, comprising:
a radiation source which is adapted to emit a polarized and non-homogenized radiation beam toward a de-polarizer and homogenizer;
a de-polarizer and homogenizer, for converting the non-homogenized and polarized radiation beam to a homogenized and de-polarized radiation beam; and
optics, for directing the homogenized and de-polarized radiation beam towards the substrate, such as to assist in removing at least one particle from the substrate.

2. Apparatus according to claim 1, further comprising a motion assembly, which is adapted to cause the homogenized and de-polarized radiation beam to scan the surface so as to clean at least an area of the surface in which the contaminant is located.

3. Apparatus according to claim 2 wherein the motion assembly comprises a chuck, for supporting the substrate and introducing a relative movement between the substrate and the homogenized and de-polarized radiation beam.

4. Apparatus according to claim 3, wherein the chuck is a non-contact chuck.

5. Apparatus according to claim 1, wherein the substrate is a semiconductor wafer, a mask, a reticle, or a flat element requiring a very high standard of cleanliness.

6. Apparatus according to claim 1, wherein the motion assembly is adapted to receive position coordinates of a particle, and to cause the homogenized and de-polarized radiation beam to clean the surface locally at a location indicated by the coordinates.

7. Apparatus according to claim 1 further comprising a fluid inlet, which is adapted to deposit an energy transfer medium on the surface in the area of the particle; and
whereas the homogenized and de-polarized radiation beam is directed onto the area, wherein the energy is absorbed by the medium, thereby causing local evaporation of the medium, so as to assist in a removal of the particle.

8. Apparatus according to claim 1 wherein the homogenizer and de-polarizer comprises a multi-mode fiber.

9. The apparatus of claim 8 wherein the homogenizer and de-polarizer further comprises a retarding plate located at proximity to the input of the multi-mode fiber in the path of the radiation beam.

10. Apparatus according to claim 8 whereas a length of the multi-mode fiber exceeds 90 centimeter.

11. Apparatus according to claim 8 whereas the homogenized and de-polarized radiation beam is directed towards the substrate at a substantially normal angle.

12. Apparatus according to claim 1 whereas the homogenized and de-polarized radiation beam is directed towards the substrate at a substantially normal angle.

13. Apparatus according to claim 1 wherein the radiation source comprises a radiation wavelength converter.

14. Apparatus of claim 1 further comprising:
a cooling device, which is adapted to cool a region of the substrate in a vicinity of a particle on the surface of the substrate, so as to cause a fluid in contact with the surface to form a frozen film in the vicinity of the particle; and
whereas the homogenized and de-polarized radiation beam is directed toward the film so as to cause rapid evaporation due to an absorption of at least a portion of the beam in the film, thereby assisting in dislodging the particle from the surface

15. Apparatus of claim 1 further comprising fiber optics.

16. Apparatus according to claim 1 further comprising a suction unit for removing dislodged particles.

17. A method for cleaning a surface of a substrate, comprising:
converting a de-homogenized and polarized radiation beam to a homogenized and non-polarized radiation beam;
directing the homogenized and non-polarized radiation beam towards the substrate such as to assist in dislodging at least one particle from the substrate.

18. Method according to claim 17, further comprising scanning the surface by the homogenized and de-polarized radiation beam so as to clean at least an area of the surface in which a particle is located.

19. Method according to claim 17, wherein the substrate comprises a semiconductor wafer, and wherein the surface is a front side of the wafer.

20. Method according to claim 17 further comprising receiving position coordinates of the particle on the substrate; and causing the homogenized and de-polarized radiation beam to clean the surface locally at a location indicated by the coordinates.

21. Method according to claim 17 further comprising:
depositing an energy transfer medium on the surface in the area of the contaminant; and
directing the homogenized and de-polarized radiation beam onto the area, wherein the energy is absorbed by the medium, thereby causing local evaporation of the medium, so as to dislodge the particle.

22. Method according to claim 17 wherein the step of converting comprises passing the non-homogenized and polarized radiation beam through a multi-mode fiber.

23. A method of claim 22 wherein the step of converting further comprising directing the radiation beam through a retarding plate located in succession of an output of the multi-mode fiber in the path of the radiation beam.

24. A method according to claim 22 whereas a length of the multi-mode fiber exceeds 90 centimeter.

25. A method according to claim 17 whereas the homogenized and de-polarized radiation beam is directed towards the substrate at a substantially normal angle.

26. Method according to claim 17 further comprising a preliminary step of converting a wavelength of the polarized and de-homogenized radiation beam.

27. Method of claim 17 further comprising a preliminary step of cooling a region of the substrate in a vicinity of a particle on the surface of the substrate, so as to cause a fluid in contact with the surface to form a frozen film in the vicinity of the particle; and
whereas the step of directing comprises directing the homogenized and de-polarized radiation beam toward the film so as to cause rapid evaporation due to an absorption of at least a portion of the beam in the film, thereby assisting in dislodging the particle from the surface

28. Method of claim 17 further comprises providing suction so as to remove a dislodged particle.
